(19) United States
(12) Patent Application Publication
(10) Pub. No.: US 2006/0028099 A1
(43) Pub. Date: Feb. 9, 2006

(54) Composite acoustic matching layer

(76) Inventor: Gregg W. Frey, Issaquah, WA (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/912,395

(22) Filed: Aug. 5, 2004

(51) Int. Cl. H01L 41/08

(52) U.S. Cl. 310/334

(57) ABSTRACT

A matching layer is formed as a composite, such as a 2-2 or a 1-3 composite. The base material forms some portion, such as 5 or more percentage by volume, of the composite matching layer and volume. The in-fill, bonding or acoustically isolating material holds the sections of base material together and provides for control of the stiffness and cross coupling. By using an electrically conductive base material, electrical conductivity is provided from a top surface to a bottom surface. The composite is easily manufactured using dicing of a base material, filling of the kerfs and curing the filled kerfs.

### BACKGROUND

The present invention relates to acoustic matching layers. In particular, an acoustic matching layer is provided for an ultrasound transducer.

To design effective broadband acoustic arrays, a wide variety of acoustic matching layer impedances are used. Conventionally, epoxies are filled with particles to provide a desired density and sound of speed. Variations in the volume of filler and type of filler may be used for providing different densities and sound speeds. Alternatively, a sheet of homogenous material with the desired density and sound speed is used. However, homogenous materials with appropriate density and sound speed are limited. The range of impedances available for filled epoxies is also limited due to viscosities, settling and other issues. To provide electrically conductive matching layers, the materials are even more limited. Filled epoxies may provide poor electrical conduits. Natural or manmade materials may have good acoustic properties but poor handling properties, such as being difficult to bond or unstable.

Composites are used for the transducer. 1-3 and 2-2 composites associated with posts and beams of material are provided for transduction materials. Piezoelectric ceramic is diced into posts or beams, and the resulting kerfs are filled with an epoxy. Such composite manufacture may allow for flexibility in the transducer material for use with curved arrays.

### BRIEF SUMMARY

By way of introduction, the preferred embodiments described below include composite matching layers and methods for forming a matching layer of an ultrasound transducer. A matching layer is formed as a composite, such as a 2-2 or a 1-3 composite. The base materials form any % of the composite matching layer by volume, such as 5, 10, 20, 30, 50 or other percentage is provided in embodiments discussed below. The in-fill, bonding or acoustically isolating material holds the sections of base material together and provides for a control of the stiffness and cross coupling. By using an electrically conductive base material, electrical conductivity is provided from a top surface to a bottom surface due to the post or beams of base material in the composite. The composite is easily manufactured using dicing of a base material, filling of the kerfs and curing the filled kerfs.

In a first aspect, a composite matching layer is provided for ultrasound transducers. A base material is at least ten percent of the composite matching layer in volume. Bonding material is less than ninety percent of the composite matching layer in volume. The composite is a 2-2 or 1-3 composite.

In a second aspect, a matching layer is provided for ultrasound transducers. A composite structure of conductive material extends through the matching layer. The composite structure also includes acoustically isolating material.

In a third aspect, a method is provided for forming a matching layer of an ultrasound transducer. A base material is diced. The dicing provides kerfs in the base material. The kerfs are filled. The filled kerfs and the base material are a composite. The composite material is positioned as a matching layer adjacent to an ultrasound transducer.

The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is a top view of one embodiment of a composite matching layer;

FIG. 2 is a top view of a portion of another embodiment of a composite matching layer;

FIG. 3 is a top view of one embodiment of a matching layer positioned relative to elements of a transducer; and

FIG. 4 is a flow chart diagram of one embodiment of a method for forming a matching layer of an ultrasound transducer.

### DETAILED DESCRIPTION OF THE DRAWINGS AND PRESENTLY PREFERRED EMBODIMENTS

By forming a composite matching layer, such as a 1-3 or 2-2 type of composite rather than a filled particulate, a base material may be selected with an impedance that may be tailored or controlled by the dicing or forming of kerfs to be in-filled with bonding or other materials. 2-2 and 1-3 composites provide for base material that extends from a top surface to a bottom surface as a continuous structure or material, allowing for convenient electrical conductivity.

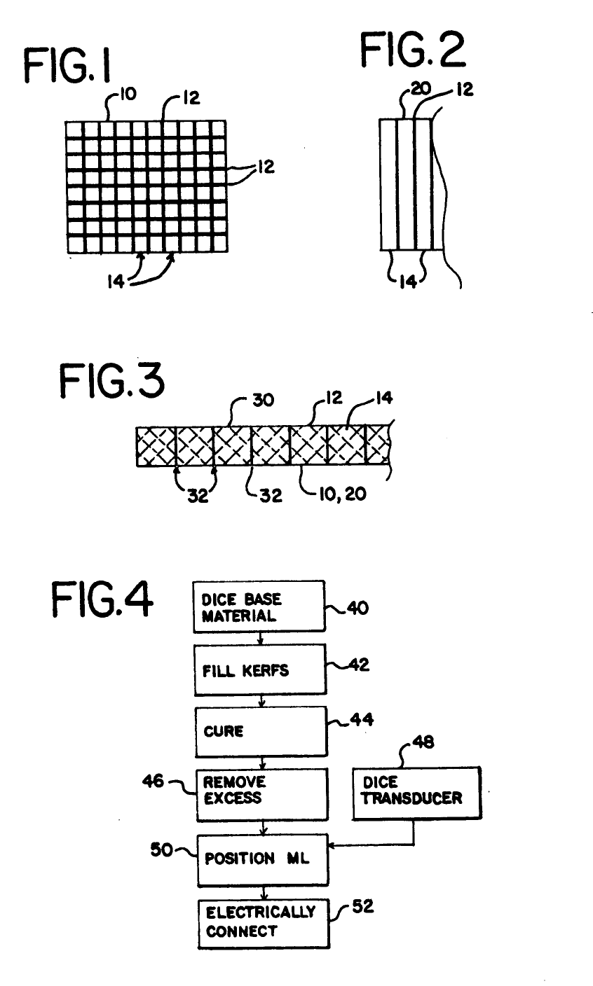

FIG. 1 shows one embodiment of a composite matching layer 10. The composite matching layer 10 includes in-fill material 12 and base material 14. Additional, different or fewer components may be provided, such as providing a filler or particles within the in-fill material 12. The composite matching layer 10 has any of various acoustic impedances and resulting sounds of speed based on material selections and distribution. The composite matching layer has a thickness appropriate for a matching layer 10 on a given transducer, such as a thickness of 300 microns. Other thicknesses may be used, including a thickness that varies along one or two dimensions. The width and the length of the matching layer 10 are selected for use with the desired ultrasound transducer, such as dimensions appropriate for a 1, 1.25, 1.5, 1.75 or 2 dimensional array.

The base material 14 is any homogeneous or composite material having a desired acoustic or other property. In one embodiment, the base material 14 is a graphite material. For example, a sheet of graphite, sheet of metal filled graphite or other graphite compound is provided. In other embodiments, conductive polymers are used. Graphite materials and conductive polymers are conductive for allowing electrical current through the base material 14. Non-conductive base materials may also or alternatively be used.

As shown in FIG. 1, the base material 14 is provided as a plurality of posts in a grid pattern. The posts may be of any shape, such as square, rectangular, circle, triangular, hexagonal or other shapes that are uniform or vary as a function of position within the composite matching layer 10. In one embodiment, the grid pattern has a pitch of about less than 400 microns but a greater pitch may be used. The bonding material 12 is within the kerfs formed in the grid pattern. A pitch that varies as a function of either dimension along the matching layer 10 may be used in alternative embodiments.

The in-fill material 12 is a bonding material and/or acoustically isolating material. For example, the in-fill material 12 is an epoxy, silicone, urethane, combinations thereof or other now known or later developed material. The in-fill material 12 bonds to the base material 14. The in-fill material 12 have many of various desired stiffnesses or cross coupling behaviors.

The base material 14 is a portion of the composite matching layer, such as 5, 10, 20, 30, 50 or other percentage of the volume. The in-fill material 12 is another portion of the composite matching layer, such as less than 95, 90, 80, 70, 50 or other percentage by volume. For example, the base material is more than 75 percent of the matching layer by volume. Additional materials may be provided so that the base and in-fill material 12, 14 make up less than 100 percent by volume of the matching layer 10. The volume fraction of the base material 14 and the in-fill material 12 may control the acoustical and handling properties of the composite matching layer 10. For example, a 50 micron blade is used to dice the base material 14 at a pitch of 200 Microns on a grid pattern as shown in FIG. 1. Such dicing may remove about 20 percent of the base material 14. By using the 50 Micron blade at a pitch of 400 Microns, a lesser percentage of base material 14 is removed. Various combinations of blade widths, pitches, dicing or kerfs shapes and the Young's modulus of the in-fill material 12 may be used to control the acoustic impedance and other properties. Tapered or stepped kerfs sections may allow for a greater range of impedance transformation throughout the thickness of the composite matching layer 10.

FIG. 1 shows a 1-3 type composite structure. FIG. 2 shows a 2-2 composite structure 20. The 1-3 and 2-2 types provide for connectivity along a number of dimensions, such as a 1-3 type having posts connected structurally along one dimension through the composite and such as a 2-2 type having bars connected structurally along two dimensions through the composite. For the 2-2 composite, the base material 14 is a plurality of bars separated along one dimension by in-fill material 12. In alternative embodiments, the composite matching layers 10, 20 are combined to provide one section with a 1-3 type structure and another section with the 2-2 structure. Other composite structures may be used. Each phase in a composite may be self-connected in zero, one, two or three dimensions. For a two-phase composite, there are ten connectivities from 0-0 to 3-3. The first number represents the connectivity of the active phase or base material 14. The base material 14 has a 1, 2 or 3 connectivity in various embodiments, but a 0 connectivity may be used.

Due to the composite structures shown in FIG. 1 and 2, electrical conductivity may be provided. The matching layer has top and bottom surfaces. The base material of posts, bars, combinations thereof or other shapes extends from the top surface to the bottom surface. The base material 14 extends without structural separation between the top and bottom surfaces of the matching layer, allowing for electrical conductivity and/or more uniform or homogeneous acoustical impedance. The through conduction is maintained in the Z or thickness direction.

FIG. 3 shows the composite matching layers 10, 20 positioned to an array of elements 30. For example, the matching layer 10, 20 is positioned on top surface of the array of elements 30 between the elements 30 and a lens. An additional matching layer of the same or different structure may be provided above or below the composite matching layer 10, 30. In one embodiment, an additional matching layer is positioned adjacent to the slab of transducer material. The transducer material and the matching layer 10, 20 are diced to define the elements 30. The kerfs common to the additional matching layer and the elements 30 are filled and cured. The composite matching layer 10, 20 is then positioned adjacent to the additional matching layer. The composite matching layer 10, 20 is free of the kerfs common to the element 30 and the additional matching layer. The in-fill material 12 provides for sufficient reduction of cross coupling to allow a different or uncommon kerfs structure.

The array of elements 30 has a first pitch, and the structure of the base material 14 is provided at a different pitch, such as a pitch that is less than the pitch of the element 30. Any relative pitch may be used. In one embodiment, the pitch of the base material 14 within the composite matching layer 10 is less than a pitch of elements of a transducer array. For example, elements of the transducer array have a pitch of 400 Microns. The pitch used for the composite matching layer 10 is 100 to 150 Microns. Larger or smaller pitches or relative pitch differences may be used.

As shown in FIG. 3, the grid pattern of the composite matching layer 10, 20 is at an angle to the kerfs 32 separating the elements. Any relative angles may be used, such as greater than 10 degrees and less than 80 degrees. For example, the angle is a 45 degree angle as shown in FIG. 3. By providing the orientation of the composite matching layer 10, 20 at an angle to the direction of the kerfs 32, larger pitch composite matching layers 10, 20 may be used on finer pitch arrays without precise alignment. In alternative embodiments, a 0 or 90 degree angle is provided such that the kerfs 32 separating the elements 30 are parallel and/or perpendicular to the grid or linear pattern of the in-fill material 12 separating the base material 14.

FIG. 4 shows one embodiment of a method for forming a matching layer of an ultrasound transducer. Additional, different or fewer acts may be provided in the same or different order than shown in FIG. 4. For example, acts 40-44 are provided without acts 46-52. As another example, acts 40-46 are provided without acts 48-52. Act 48 may be performed prior to or after act 50.

In act 40, a base material is diced. The dicing is performed with a blade, but lasers or other cutting implements may be used. A sheet or other shaped based material is diced in any of various patterns, such as a long a grid pattern of perpendicular lines, along a one-dimensional pattern of parallel lines, along patterns for forming diamond shapes, squares, rectangles, triangles, hexagons or other shaped posts for a 1-3 composite or bars for a 2-2 composite.

In one embodiment, the dicing cuts are less than completely through the base material, such as extending kerfs through about 75 percent of the thickness. Other depths may be used. The remaining depth of material acts as a support structure. Alternatively, the base material is supported on a tape or other structure. The kerfs are then formed through the entire thickness of the base material. The components of the base material are maintained in a position relative to each other by the tape or other support structure.

Impedance may be controlled by selecting a dicing kerf width, dicing kerf pitch and/or dicing kerf shape. For example, the shape of the kerfs are tapered or stepped. The control over the kerf width, pitch, and shape may allow for selection or control of the acoustic impedance, cross coupling, stiffness or other property of the composite matching layer. The volume fraction of the base material removed by dicing allows for control of acoustic impedance. Tapered, stepped or other shaped kerfs may allow for impedance transformation through a thickness dimension.

In act 42, the kerfs formed from the dicing are filled. Epoxy, silicon, urethane, combinations thereof or other in-fill material with the desired modulus, density, elasticity, stiffness, acoustic coupling, acoustic impedance or other property are used. The in-fill material is pressed, injected or poured into the kerfs or over the base material. By filling the kerfs in the base material, the composite material is formed.

In act 44, the in-fill material positioned within the kerfs 42 is cured. A room temperature or oven based curing may be performed. In alternative embodiments, curing is not needed as the in-fill material is in a desired state as positioned within the kerfs. Excess in-fill material may be removed by pressure or other mechanisms in a non-cured state or grinding or machined off once cured.

In act 46, base material is removed. The undiced thickness or support section of the base material is removed. In the embodiment where the base material is diced to a depth of 75 percent or other number percentage of the thickness, the remaining thickness is ground off after the fill material has cured. The removed material acted as a spine or support structure for the filling and curing acts. Once the support structure is no longer needed, the structure is removed. As a result, the composite material has base material components extending from a top surface to a bottom surface and in-fill material extending from a top surface to a bottom surface.

In act 48, transducer ceramic is diced. For example, a slab of solid or composite piezoelectric material is diced to form elements. In one embodiment, one or more electrodes are diced with the transducer material for defining the elements. Additional matching layers, such as one or two other matching layers positioned on the transducer material are also diced with the transducer material, creating common kerfs through the matching layers and transducer material. The common kerfs are filled, such as filling with epoxy. In alternative embodiments, the transducer material remains undiced until after act 50 is performed.

In act 50, the composite material is positioned adjacent to an ultrasound transducer as a matching layer. Adjacent to includes positioning the composite material as a first matching layer directly adjacent to the transducer or positioning the composite material as one of two or three matching layers with a different matching layer between the transducer material and the composite material. Any alignment of the composite matching layer to the transducer elements may be used, such as random or purposeful alignment. For example, the matching layer is formed with a rectangular grid or a series of parallel lines. The kerfs associated with the composite matching layer are positioned at an angle greater than 10 degrees and less than 80 degrees to the transducer element kerfs. Other relative angles may be used, including 0 or 90 degree angles. The matching layer is bonded to the transducer elements or other materials of the transducer stack. Sintering and lamination may alternatively be used. Where the transducer has not previously been diced, the transducer and composite material matching layer are diced to form the elements. Where the transducer was previously diced, the in-fill material of the composite matching layer acts to acoustically isolate and prevent lateral cross coupling between the elements without further kerfs or dicing.

In act 52, an element of the ultrasound transducer is electrically connected through the composite material. For example, the elements of the transducers each have an electrode separated by kerfs used to form the elements. Where the electrode is not accessible due to manufacturing technique or use in a multidimensional array, electrical conductivity is provided through the matching layer. A grounding plane or other signal connectors are positioned adjacent to the matching layer for electrical connection to the different elements. Where the composite matching layer base material is a conductive material, electrical connection is provided through the matching layer on the conductive path provided through the base material.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

I (We) claim:

1. A composite matching layer for ultrasound transducers, the composite matching layer comprising:
a base material comprising at least ten percent of the composite matching layer in volume; and
a bonding material comprising less than ninety percent of the composite matching layer in volume;
wherein the base material has a 1, 2 or 3 connectivity within the composite matching layer.

2. The composite matching layer of claim 1 wherein the base material and the bonding material comprise a 2-2 composite structure.

3. The composite matching layer of claim 1 wherein the base material and the bonding material comprise a 1-3 composite structure.

4. The composite matching layer of claim 1 wherein the matching layer has top and bottom surfaces, the base material comprising posts, bars or combinations thereof extending from the top surface to the bottom surface.

5. The composite matching layer of claim 1 wherein the base material comprises a conductive material.

6. The composite matching layer of claim 5 wherein the base material comprises a graphite material.

7. The composite matching layer of claim 1 wherein the base material is in a grid pattern with a pitch of about less than 400 microns and the bonding material is within kerfs of the grid pattern.

8. The composite matching layer of claim 1 wherein the bonding material comprises one of epoxy, silicone, urethane or combinations thereof.

9. The composite matching layer of claim 1 wherein the base material comprises more than 75% of the composite matching layer by volume.

10. The composite matching layer of claim 1 positioned adjacent to an array of elements, the array of elements at a first pitch and structures of the base material at a second pitch, the second pitch less than the first pitch.

11. The composite matching layer of claim 1 positioned adjacent to an array of elements, the elements separated by first kerfs, the base material separated by second kerfs filled with the bonding material, the first kerfs at an angle greater than 10 degrees and less 80 degrees to the second kerfs.

12. The composite matching layer of claim 1 positioned adjacent to an array of elements and an additional matching layer, the additional matching layer and the array of elements having common kerfs, the composite matching layer free of the common kerfs.

13. A matching layer for ultrasound transducers, the matching layer comprising:
a composite structure of conductive material extending through the matching layer;
the composite structure having acoustically isolating material.

14. The matching layer of claim 13 wherein the conductive material comprises a graphite material.

15. The matching layer of claim 13 wherein the acoustically isolating material comprises one of: epoxy, silicone, urethane and combinations thereof.

16. The matching layer of claim 13 wherein the composite structure comprises one of a 1-3 or 2-2 composite structure.

17. The matching layer of claim 13 wherein the conductive material comprises posts or bars each extending without structural separation between a top and a bottom surface of the matching layer.

18. A method for forming a matching layer of an ultrasound transducer, the method comprising:
(a) dicing a base material, the dicing providing kerfs in the base material;
(b) filling the kerfs, the filled kerfs and base material comprising a composite material; and
(c) positioning the composite material as a matching layer adjacent to the ultrasound transducer.

19. The method of claim 18 wherein (a) comprises dicing in a grid pattern, the composite material comprising a 1-3 composite of posts of the base material.

20. The method of claim 18 wherein (a) comprises dicing along one dimension, the composite material comprising a 2-2 composite of bars of base material.

21. The method of claim 18.wherein (a) comprises dicing less than completely through the base material;
further comprising:
(d) removing base material corresponding to the undiced thickness of (a) after performing (b).

22. The method of claim 18 wherein (a) comprises dicing a conductive base material;
further comprising:
(d) electrically connecting an element of the ultrasound transducer through the composite material.

23. The method of claim 18 wherein (b) comprises filling the kerfs with one of epoxy, silicone, urethane and combinations thereof;
further comprising:
(d) curing the filled kerfs after (b) and prior to (c).

24. The method of claim 18 wherein (c) comprises positioning the composite material with the kerfs at an angle greater than 10 degrees and less than 80 degrees to transducer element kerfs.

25. The method of claim 18 -further comprising:
(d) dicing the ultrasound transducer into elements;
wherein (c) is performed after (d).
